(19) United States
(12) Patent Application Publication
(10) Pub. No.: US 2026/0113962 A1
(43) Pub. Date: Apr. 23, 2026

(54) Recessed Dummy Single Trench Gate IGBT

(71) Applicant: Alpha and Omega Semiconductor International LP, Toronto (CA)

(72) Inventors: Wenjun Li, San Jose, CA (US); Karthik Padmanabhan, Palo Alto, CA (US); Jian Wang, Portland, OR (US); Hongyong Xue, Portland, OR (US); Lei Zhang, Portland, OR (US); Zhibo Guo, San Jose, CA (US); Madhur Bobde, Sunnyvale, CA (US)

(21) Appl. No.: 18/923,570

(22) Filed: Oct. 22, 2024

(51) Int. Cl. H01L 29/739; H01L 29/06; H01L 29/423; H01L 29/66

(52) U.S. Cl. CPC H10D 12/481; H10D 12/038; H10D 62/127; H10D 64/513

(57) ABSTRACT

A semiconductor device comprising a substrate comprised of a semiconductor material having a drift region lightly doped with ions of a first conductivity type and a body region formed the substrate doped with ions of the second conductivity type. A dummy trench may be formed in the drift region. The dummy trench is formed to a depth in the substrate deeper than a bottom depth of the body region. An insulation layer formed over the substrate in the dummy trench. A dummy electrode is formed over the insulation layer in the dummy trench. The top of the dummy electrode is at a depth in the dummy trench below the bottom of the body region and a gate electrode formed in the active gate trench wherein the gate electrode extends from a portion of the body region to below the bottom of the body region in the active gate trench.

### FIELD OF THE DISCLOSURE

The present disclosure is related to semiconductor devices. More specifically, aspects of the present disclosure relate to semiconductor devices having dummy trenches.

### BACKGROUND OF THE DISCLOSURE

A major focus and desire of current transistor design is to decrease the cell pitch by reducing mesa width. Devices with decreased mesa width may feature an increased doping concentration for the drift region, which allows the thickness of the drift region to be reduced while maintaining the same blocking voltage and reducing the saturation voltage from collector to emitter (Vce) and conduction loss.

A major drawback of devices with fine pitch is an increase in switching loss and a downgrade in short circuit capability. The fast switching operation will increase dv/dt and cause electromagnetic interference (EMI) noise. Dummy cell regions for transistor devices have been proposed to improve a trade-off between on-voltage, EMI noise, and switching loss.

These prior designs for devices with dummy cell regions reduced the ratio of Gate to Collector Capacitance/Gate to Emitter Capacitance (Cgc/Cge ratio) resulting in increased voltage recovery time and switching noise that may produce electromagnetic interference (EMI).

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1 is a side view of a transistor device having improved trench electrode design according to aspects of the present disclosure.

FIG. 2 depicts a side view of an improved transistor device having dummy trenches including a dummy plug according to an aspect of the present disclosure.

FIGS. 3A-3J are side view cross-sections depicting a method for making the transistor device having an improved dummy electrode design according to aspects of the present disclosure.

FIGS. 4A-4H are side view cross-sections depicting a method for formation of a transistor device with dummy trenches having dummy electrodes and conductive dummy plugs of the type depicted in FIG. 2 according to aspects of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, examples of embodiments of the invention described below are set forth without any loss of generality to, and without imposing limitations upon, the claimed invention.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon may be used in transistor devices in accordance with aspects of the present disclosure.

In the following Detailed Description, reference is made to the accompanying drawings, which form a part hereof, and in which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n− material. Similarly, a p+ material has a higher p type net dopant (e.g., hole) concentration than a p material, and a p material has a higher concentration than a p− material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants less than about 1e¹⁴ cm⁻³ may be regarded as “lightly doped” and a concentration of dopants greater than about 1e¹⁶ cm⁻³ may be regarded as “heavily doped”.

An improvement to transistor cell design may be realized through the improved dummy trench electrode according to aspects of the present disclosure. The previous designs of dummy trenches electrodes did not allow manipulation of Cgc/Cge beyond reducing both Cgc and Cge. The improved dummy trench electrodes may increase Cgc/Cge by decreasing Cge without increasing Cgc. Thus, implementations according to aspects of the present disclosure may realize a reduction in cell area, and switching loss, with a large short-circuit safe operating area and a decrease in recovery dv/dt to reduce switching noise.

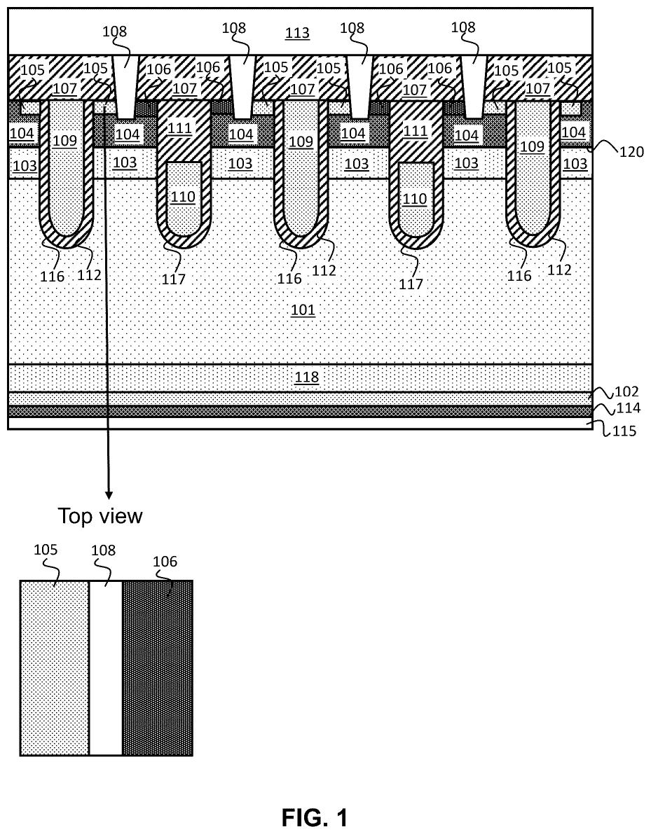

FIG. 1 is a side view cross-section of a transistor device having an improved trench electrode design according to aspects of the present disclosure. Here, the transistor device shown is an Insulated Gate Bipolar Transistor (IGBT), but aspects of the present disclosure are not so limited and may be applied to any type of trench type transistor device for example and without limitation Metal-Oxide-Semiconductor Field Effect Transistors (MOSFET), and Junction Field Effect Transistors (JFET). As shown in FIG. 1, the improved transistor device may include a semiconductor material substrate having an epitaxial layer lightly doped with ions of the first conductivity type formed on a base heavily doped with ions of the first conductivity type. The base here may be a buffer layer 102 and a portion of the epitaxial layer may form a drift region 101. A carrier stored layer 103 may be formed in an upper portion of the substrate and more heavily doped with ions of the first conductivity type than the drift region 101. A body region 104 may be formed in the substrate composition above the carrier stored layer 103 and doped with ions having the second conductivity type. An emitter region 105 may be formed in an upper area of the body region 104 and be heavily doped with ions of the first conductivity type. A body contact region 106 may also be formed in the upper area of the body region 104 across an emitter plug 108 from the emitter region 105 and heavily doped with ions having the second conductivity type. The emitter plug provides an electrically conductive path through an insulation layer between the emitter region 105 and an emitter metal layer 113.

One or more active gate trenches 116 may be formed in the substrate composition. In the implementation shown the device includes three active gate trenches 116. The one or more gate trenches may extend from a top of the substrate composition into the drift region 101 below the body region 104. Additionally, one or more dummy trenches 117 are formed in the substrate composition. As shown here the substrate composition includes two dummy trenches 117. The dummy trenches 117 may extend from the top surface of the substrate composition to a region below the bottom of the body region 104.

The insulation layer may include a top insulation layer portion 107, active gate insulation layer portion 112 and dummy insulation layer portion 111. The top insulation layer portion 107 may be disposed on top of the substrate composition. The active gate insulation layer 112 may line the sides and bottom of the active gate trenches 116. The dummy insulation layer 111 may line the sides and bottom of each the dummy trenches. The insulation layer may be made from any dielectric material for example and without limitation silicon dioxide, silicon nitride, Aluminum Oxide (Al2O3), etc.

Each of the gate electrodes 109 fills a portion of a corresponding active gate trench 116 over the active gate insulation layer portion 112 and runs from the top substrate composition to below a bottom of the body region 104. Each active gate electrode is conductively coupled to a gate metal layer (not shown), e.g., by a conductive gate runner at the edge of the device (not shown). The gate electrode 109 may be made from any suitable conductive material for example and without limitation n-doped polycrystalline silicon or p-doped polycrystalline silicon. In the implementation shown the device includes three gate electrodes 109 but aspects of the present disclosure are not so limited and there may be any number of gate electrodes.

A dummy electrode 110 is located in a portion of each of the dummy trenches 117 over a portion of the dummy insulation layer 111 near the bottom of the corresponding dummy trench below a bottom 120 of the body region bottom in the semiconductor substrate. The dummy electrode 110 may extend from a portion of the carrier stored layer 103 to below the bottom of the carrier stored layer in the dummy trench 117. In the illustrated implementation each dummy electrode 110 is electrically insulated from the semiconductor substrate by portions of the dummy insulation layer 111 in the corresponding dummy trench. Additionally, the dummy electrode 110 may be conductively coupled to the gate metal (not shown) by a conductive gate runner at the edge of the device (not shown). The dummy electrode may be any suitable conductive material for example and without limitation n-doped polycrystalline silicon or p-doped polycrystalline silicon. As shown here the device includes three active gate electrodes 109 and two dummy electrodes 110 but aspects of the present disclosure are not so limited and there may be any number of active and dummy gate electrodes.

In the implementation shown each dummy trench 117 with dummy electrode 110 is located between two active gate trenches 116 each having an active gate electrode 109. Aspects of the present disclosure are not so limited. There may be any number of dummy trenches having a dummy electrode between the active gate trenches. Furthermore, the number of dummy trenches between active gate trenches may be used to manipulate the Cgc/Cge. Thus, the improved device allows for greater customization of Cgc/Cge as compared to previous device designs having dummy trenches.

In the implementation depicted in FIG. 1, the emitter metal layer 113 may be formed over the top insulation layer 107 and the semiconductor substrate composition. The top insulation layer 107 covers the top of the substrate composition, the active gate electrodes 109 and the dummy insulation layer 111 and insulates the substrate composition and gate electrodes 109 from the emitter metal layer 113 and gate metal layer (not shown here). The emitter metal layer may be made from any suitable conductive material, for example a metal such as aluminum, copper, and n-doped polycrystalline silicon or p-doped polycrystalline silicon.

As mentioned above, conductive emitter plugs 108 are conductively coupled with the emitter metal layer 113 as shown here, the emitter plugs 108 are in contact with the metal layer 113. The emitter plugs 108 extend through the top insulation layer 107 and into the substrate composition. In the implementation shown the emitter plug extends into the semiconductor substrate composition to a depth below the emitter region 105 and body contact region 106. As shown the emitter regions 105 and body contact regions 106 are formed on opposite sides of the contact plug and the gate 116 is located on a side of the emitter region 105 opposite the side bordering the conductive emitter plug 108 in the semiconductor substrate composition. Similarly, each of the dummy trenches 117 is located on a side of the body contact region 106 opposite the side bordering the conductive emitter plug 108 in the semiconductor substrate composition. In other words, in a device with multiple emitter regions and body contact regions, at least two emitter regions are located next to an active gate trench in the substrate on opposing sides of the active gate trench and two body contact regions are located next to a dummy trench in the substrate on opposing sides of the dummy trench. The conductive emitter plug may be any suitable conductive material, by way of example and not by way of limitation a metal with barrier metal for example and without limitation tungsten with a titanium nitride barrier layer. In the implementations shown there are four conductive emitter plugs 108 but it should be understood that aspects of the present disclosure are not so limited and there may be any number of emitter plugs suitable for proper device function. Additionally, while the emitter plugs shown extend to a depth of the below the bottom emitter regions and body contact regions aspects of the present disclosure are not so limited and the emitter region may extend to any depth in in the body region 104 to conductively couple with the emitter region when a sufficient voltage between the gate electrode and the emitter electrode to place the conductive ‘on’ state.

On the backside (bottom) of the substrate composition a graded portion of the epitaxial layer 118 may be formed above the buffer layer 102. The graded portion of the epitaxial layer 118 may be doped on a gradient with the doping concentration greater near the buffer layer and decreasing through the substrate to its lowest point near the drift region 101. The doping gradient may be linear, exponential, quadratic, etc.

A collector region 114 may be formed below the buffer layer 102. The collector region may be heavily doped with ions of the second conductivity type (P-type for IGBT). A collector metal layer 115 may be formed below the collector region 114 and is conductively coupled with the collector region when the device is in the “On” state. The collector metal layer 115 may be any suitable conductive material such as, and without limitation, aluminum, copper, gold, silver iron, magnesium, or an alloy thereof or a metal with a barrier layer such as tungsten with a titanium nitride barrier layer or without a barrier layer for aluminum.

Thus, in operation, the dummy electrodes decrease the gate-emitter capacitance Cge of the improved device described by FIG. 1 without a corresponding decrease in the gate-collector capacitance Cgc. The dummy electrode, which is at gate voltage when the device is active, accumulates charge without forming an additional channel thus increasing the Cgc because there is no corresponding structure increasing the Cge, the net effect is increasing the Cgc/Cge resulting in adjusting switching speed to reduce dv/dt and to reduce EMI noise, with a large short circuit safe operating area when compared to prior designs of devices with dummy trenches.

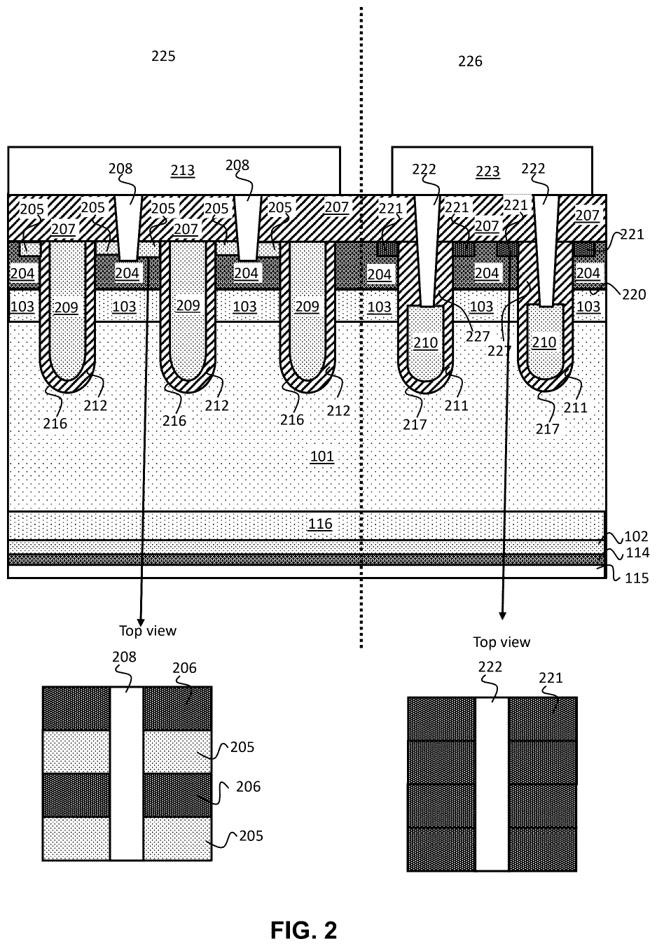

FIG. 2 depicts a side view of an improved transistor device having dummy trenches including a dummy plug according to an aspect of the present disclosure. This implementation is similar to the implementation shown in FIG. 1, but the semiconductor substrate composition is separated into an active area 225 and a dummy area 226 having dummy trenches with conductive dummy plugs. The active area 225 here includes active gate trenches 216 lined with a gate trench insulation layer 212, each active gate trench 216 having a conductive gate electrode 209 disposed over the gate insulation layer in the gate trench. The active area 225 additionally includes emitter regions 205 disposed in an upper portion of the body regions 204 and conductive emitter contact plugs 208. Each emitter contact plug 208 is disposed next to an emitter region 205 and is in conductive contact with the emitter region when the device is in the “On” state. Additionally, the active area 225 includes body contact regions 206, each of which is disposed on both sides of an emitter contact plug 208 as shown in top view layout of FIG. 2. As discussed above the emitter regions 205 may be heavily doped with ions of the first conductivity and the body contact regions may be heavily doped with ions of the second conductivity type. The body region 204 may be doped with ions of the second conductivity type. An insulation layer 207 is disposed over the active area 225 and dummy area 226 on a surface of the semiconductor substrate composition proximate the emitter regions 205 and body contact regions 206. An emitter metal layer 213 is disposed on the insulation layer 207 in the active area 225 and is electrically isolated from a gate metal layer 223, which is disposed over the dummy area 226. Additionally, the active gate electrodes 209 are conductively coupled to the gate metal layer 223. The gate electrodes may for example and without limitation be connected to the gate metal layer 223 by conductive gate runners at the edge of the device (not shown).

Likewise, the dummy area 226 includes dummy trenches 217 formed in the semiconductor substrate and each dummy trench having a dummy trench insulating layer 211 disposed on surfaces inside the dummy trench. A conductive dummy electrode 210 is disposed near the bottom of each of the dummy trenches 217 over the dummy trench insulating layer 211 and below the body region bottom 220. The dummy electrode 210 may extend from a portion of the carrier stored layer 103 to below the bottom of the carrier stored layer in the dummy trench 217.

In this implementation an electrically conductive dummy plug 222 extends from the gate metal layer 223 through the top insulation layer 207 and a dummy plug portion 227 of the dummy insulation layer 211 to make conductive contact with the dummy electrode 210 in each of the dummy trenches 217. As shown the dummy plug portion 227 of the dummy insulation layer is thicker than the portion of the dummy insulation layer next to the dummy electrode 210, on the side or bottom of the dummy trench 217. The thicker insulation layer portion 227 near the dummy plug 222 reduces the electric field effect from the dummy plug thus preventing the dummy plug from acting as a gate electrode. The thicker insulation layer portion 227 can reduce gate to emitter capacitance Cge. The dummy plug may be made from any suitable conductive material such as, without limitation a metal with a barrier layer (e.g., tungsten with a titanium nitride barrier layer)

The dummy area 226 further includes one or more dummy body contact regions 221 formed near a side of each of the dummy trenches 217 in the body region 207. The dummy contact regions 221 may be heavily doped with ions of the second conductivity type. Unlike the active area 225 the dummy area 226 does not include an emitter contact conductively coupling substrate regions to the emitter metal. Instead, the gate metal 223 is formed on the insulation layer 207 over at least a portion of the substrate composition including dummy trenches 217 and dummy electrodes 211 in the dummy area 226. As discussed above the gate metal 223 is conductively coupled with the dummy electrodes 210 in the dummy area 226 via the dummy plugs 222.

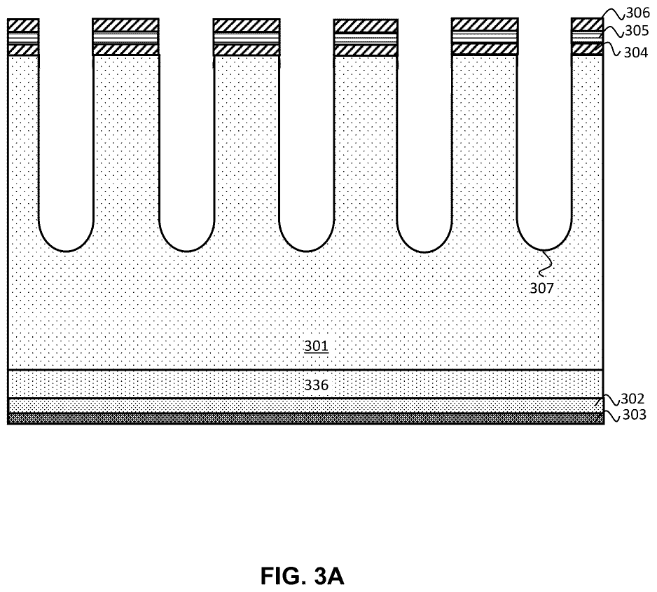

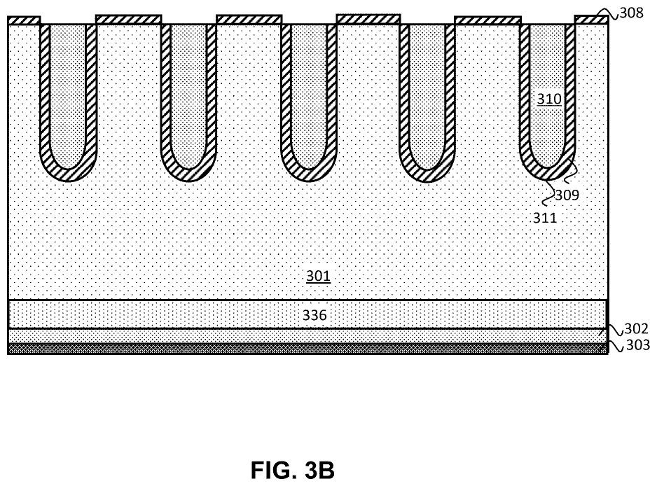

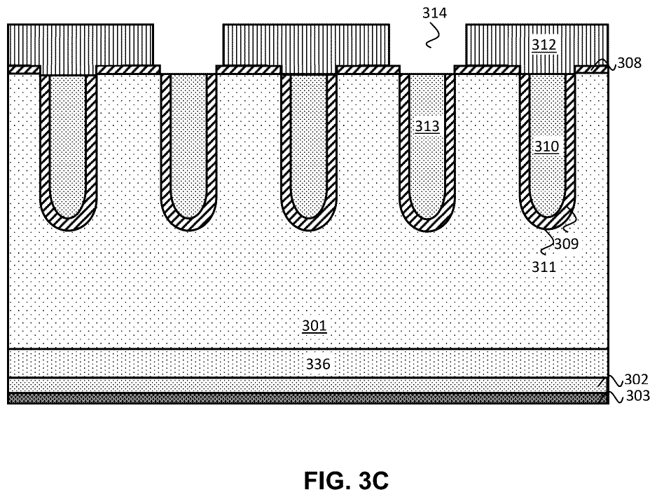

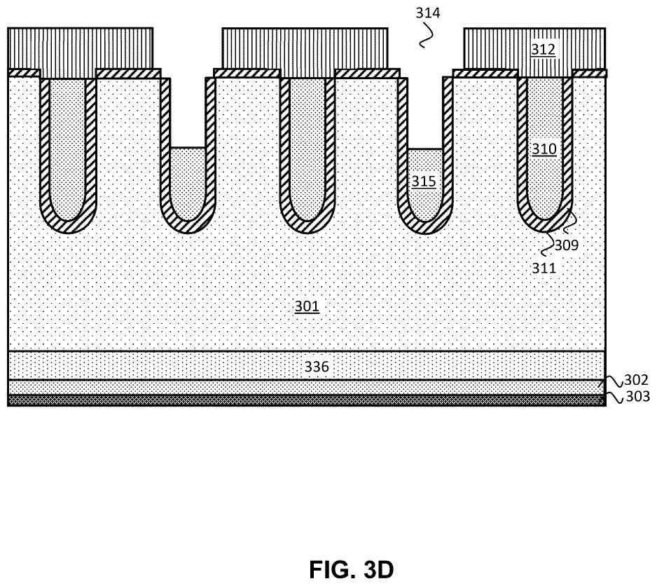

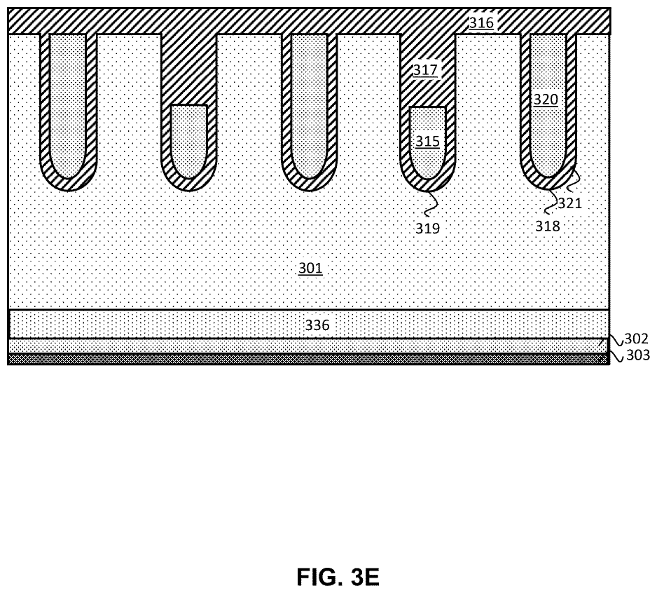

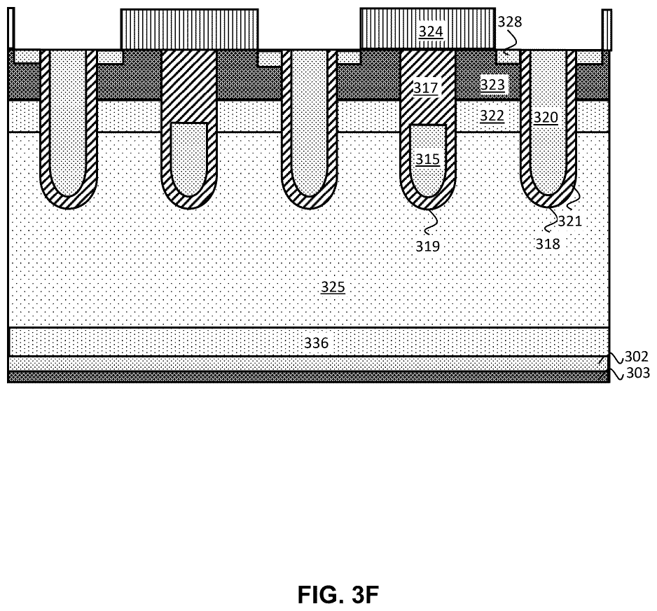

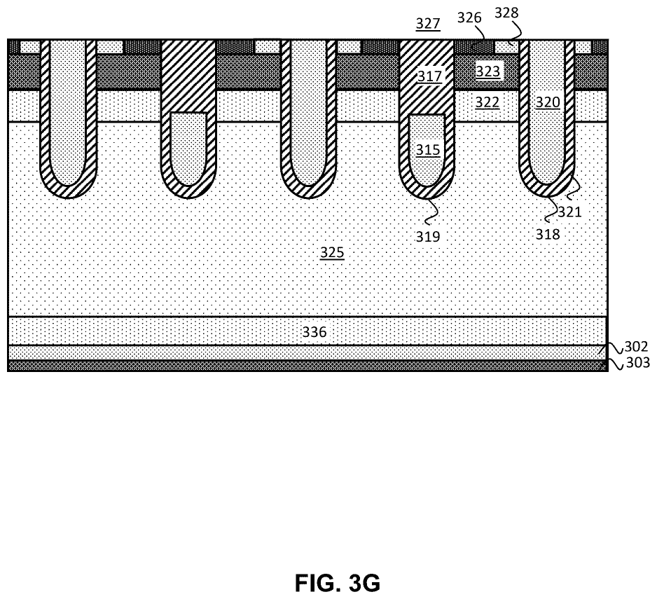

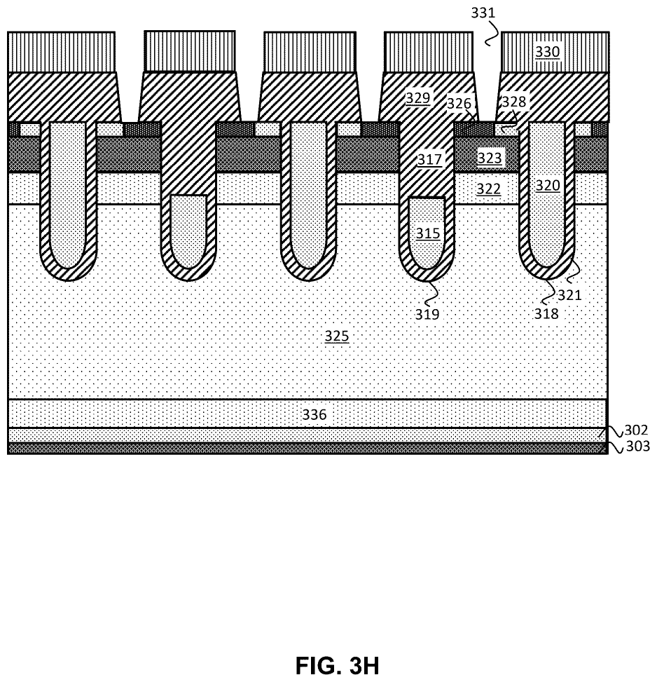

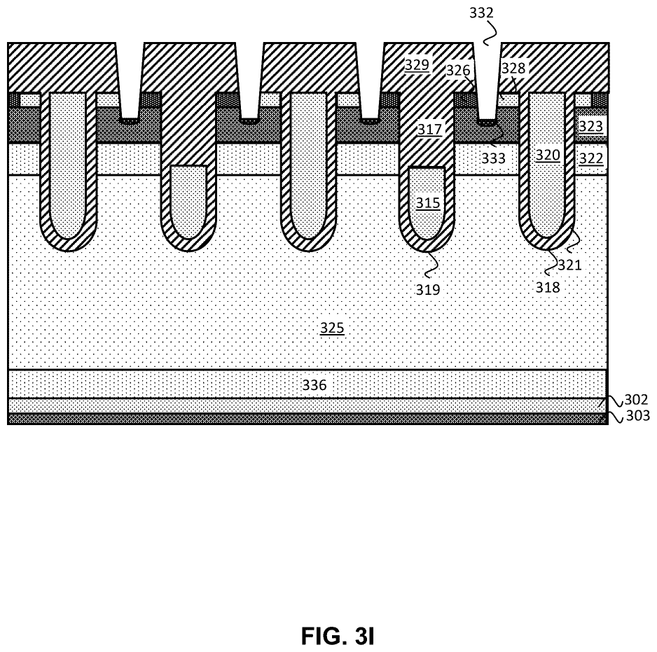

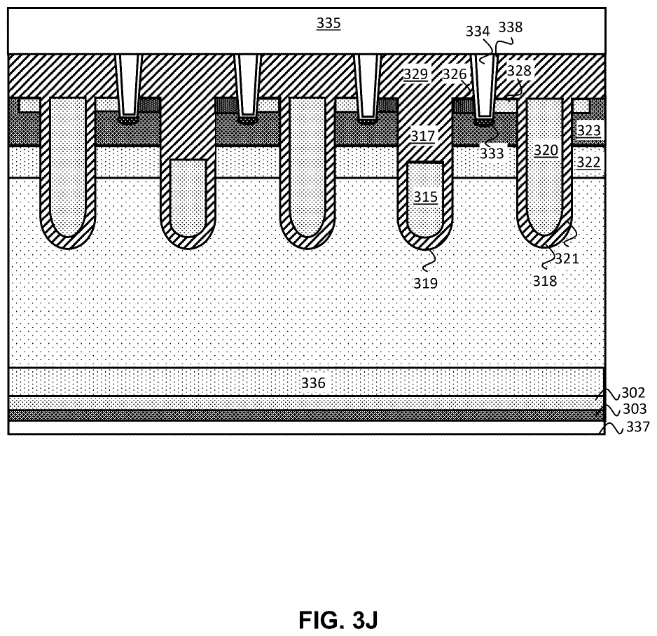

FIG. 3A-3J are side views depicting a method for making the transistor device having the improved dummy electrode design according to aspects of the present disclosure.

Starting at FIG. 3A, an epitaxial layer 301 and 302 may be grown on a substrate 303 with heavily doped with ions of the second conductive type (IGBT is P-type collector) via suitable processes for example and without limitation chemical vapor deposition (CVD) or physical vapor deposition (PVD) processes. The epitaxial layer 301 may be formed with or may be implanted to have a light dopant ion concentration. The epitaxial layer 302 may be heavily doped with ions of the first conductivity type. Alternatively, the collector contact layer 303 may be formed via epitaxial growth using suitable processes for example and without limitation CVD. Additionally, during epitaxial growth, a graded region 336 having an ion concentration gradient may be formed. The graded epitaxial region 336 may have a linear, exponential, quadratic etc. gradient with the highest concentration near the back side of the device. A silicon oxide layer 304 may be deposited or otherwise formed over the surface of the epitaxial layer 301 through holes in a developed mask to a thickness of for example and without limitation around 1000 Angstroms via the suitable processes for example and without limitation CVD, or PVD, or thermal oxidation processes. After the first silicon oxide layer 304 is created, the nitride layer 305 may be deposited over the oxide layer 304 with a thickness of for example and without limitation about 500 angstroms. The silicon nitride (SIN) layer 305 may be deposited by CVD or PVD processes. Finally, a top oxide layer 306 of the hard mask may be applied over the nitride layer via suitable processes for example and without limitation an oxide layer with a thickness of greater than 0.6 microns may be created, e.g., by CVD or PVD or spin on oxide processes.

Next, a photoresist layer is coated on top of ONO layer (OX/SIN/OX) and forms photoresist mask after UV light exposure and development. Then implement plasma reactive ion etching (RIE) etch to etch silicon to form trench pattern. The trench depth is in the range of 3 micrometers to 5 micrometers in the epitaxial layer 301.

After formation of silicon trench, the developed photoresist mask may be removed. The developed mask may be removed by any suitable mask remover leaving the nitride hard mask 304, 305, 306 as a negative version of the developed mask.

Next, to finish the trenches a sacrificial oxide layer is formed in the trenches via, without limitation thermal oxidation. The sacrificial oxide layer may be for example and without limitation around 250 Angstroms (2.5×10⁻⁸ m) in thickness. Subsequently the sacrificial oxide layer within the trenches 307 is removed to create the final trench 311 width by for example and without limitation selective wet etching.

Next, as shown in FIG. 3B, the trench insulation layer 309 may then be grown on the inside walls and bottom of the trenches 311 via, for example and without limitation, thermal oxidation, CVD or PVD processes. The conductive trench electrodes 310 are then deposited in the trenches 311 over the trench insulation layer 309 and on the top surface of the substrate composition and nitride hard mask. The trench electrodes may be formed via any suitable deposition method for way of example and not by way of limitation CVD or PVD processes. After formation of the trench electrodes 311 the excess electrode material may be removed via planarization or CMP. The trench electrode material may be any suitable conductive material such as, and without limitation, a n-doped poly crystalline silicon or p-doped polycrystalline silicon.

After removal of the excess electrode material, the Oxide and Nitride hard mask layers 305, 306 are removed via suitable hard mask removal methods, for example and without limitation dry etching, wet etching with HF or H₃PO₄, Buffer oxide etching, etc., and/or Chemical and Mechanical Polishing (CMP). After removal of the 306 and 305 hard mask a silicon oxide layer 308 from initial oxide layer 304 remains over portions of the exposed surface of the epitaxial layer 301 between the trenches.

As shown in FIG. 3C. a developed patterned mask 312 may be applied to the top surface of the semiconductor substrate composition. The developed patterned mask may be created by first applying an undeveloped masking material to the top surface and patterning the mask with a suitable patterning method (e.g., a light pattern for a photoresist mask). The masking material is then developed to form a patterned mask. By way of example and without limitation, a photoresist masking material may be exposed to a light pattern and subsequently developed and washed with an appropriate photoresist developer leaving the patterned mask on the substrate. As shown the developed mask 312 includes openings 314 in areas of the substrate corresponding to precursor dummy trench electrodes 313 and also includes portions that cover the gate electrodes 310.

Next as depicted in FIG. 3D, the conductive precursor dummy electrodes 313 are etched to their final depth to form dummy electrodes 315. Here, special care is taken to ensure that the dummy electrodes 315 are etched such that the top of each dummy electrode 315 is below a bottom of a body region which will be implanted into the substrate in later steps. The precursor dummy electrodes 313 may be etched to form the dummy electrodes 315 by any suitable etching method for example and without limitation polycrystalline silicon dry etch.

The developed patterned mask 312 may then be removed by any suitable mask removal method, for example and without limitation, plasma ash and chemical washing. Next a dielectric material layer 316 may be deposited over the top surface of the substrate composition. The dielectric material fills the dummy trenches 319 over the dummy electrode 315 forming a top portion of the dummy electrode insulation layer 317. The dummy electrode 315 may extend from a portion of the carrier stored layer 322 to below the bottom of the carrier stored layer in the dummy trench 319. The Active gate trenches 318 are now differentiated from the dummy trenches 319 as the active gate trenches 318 are filled with a conductive gate electrode 320 formed over the active gate insulation layer 321 approximately to the surface of the epitaxial layer, as shown in FIG. 3E. The dielectric material may be any suitable dielectric material layer 316 for example and without limitation silicon dioxide. Portions of the dielectric material may then be removed from the top surface of the substrate composition by, for example and without limitation, planarization and/or CMP leaving dummy trench portion 317 of the insulation layer.

As shown in FIG. 3F the substrate composition may first be doped with ions of the first conductivity type (n-type) to a depth deeper than the body region (yet to be formed) to form the carrier stored layer 322. The carrier stored layer 322 may be doped to a concentration slightly higher than that of the drift region 325. Here, the epitaxial layer has now become the drift region 325. For example, and without limitation, the drift region may have a dopant ion concentration of 1e12 cm⁻³ to 3e15 cm⁻³ depending on different blocking voltage if for example the drift region has a concentration of 2e14 cm⁻³ then the carrier stored layer may be doped to a concentration of 4e14 cm⁻³. Next the body region 323 may be formed above the carrier stored layer 322. The body region may be doped with ions of the second conductivity type via ion implantation with a doping concentration of between 1e14 cm⁻³ and 1e16 cm⁻³ and an energy of implantation depending on the application but in some example implementations the energy may be between 80 Kiloelectronvolts (KeV) and 200 KeV. The substrate composition may then undergo thermal annealing in a furnace at between 900 and 1200 C in an inert atmosphere or vacuum to drive the body region dopants into the substrate and activate them.

Next a patterned mask 324 for creation of the n+ emitter 328 and the body contact regions 326 may be formed on the top surface of the substrate composition. The patterned mask 324 with the layout in FIG. 1 may be formed by any masking method, such as the previously discussed masking method. The emitter regions 328 are then formed through holes in the patterned mask 324 via a heavy doping method for example and without limitation, ion implantation of the first conductivity type, the doping of n+ emitter region 328 is 2 to 3 times higher than doping of body contact region 326. The developed patterned mask 324 may then be removed by any suitable mask removal method, for example and without limitation, plasma ash and chemical washing. As shown in FIG. 3G, the body contact regions may be then formed by the implantation of ions having the second conductivity type with doping is 2 to 3 times lower than emitter region 328. The oxide layer on the surface of the substrate is then dipped back to 250 Angstroms.

Low temperature oxide may then be deposited over the surface of the substrate to a thickness of 0.15 Micron. Next as shown in FIG. 3H, the top portion of the insulation layer 329 is formed on the top surface of the substrate composition. The top portion of the insulation layer 329 may be formed by any suitable dielectric layer formation method for example and without limitation, deposition of Borophosophosilicate glass (BPSG) on the surface of the substrate via deposition and annealing/reflow. The top insulation layer thickness may vary depending on the application intended for the device the top insulation layer may be 0.5 to 1 Microns in thickness An emitter contact plug patterned mask 330 is then formed over portions of the top insulation layer 329. The emitter contact plug patterned mask 330 may be formed by any suitable masking methods as discussed with other masks discussed above. Next the insulation layer is etched through holes in the emitter contact plug patterned mask 330 to form contact plug precursor trenches 331 in the insulation layer via any suitable plasma etching method, e.g., dry oxide etching. After creation of the contact plug precursor trenches 331 the emitter contact plug patterned mask 330 may be removed by a suitable removal method for example and without limitation plasma ash and chemical washing

As depicted in FIG. 3I the silicon substrate is etched at the locations of the contact plug precursor trenches 311 to form the emitter contact trenches 332. The emitter contact trenches 332 may be etched by any suitable etching method to a depth in the semiconductor substrate composition of around 0.1 to 0.4 microns. Next a bottom contact region 333 is implanted at the bottom of the emitter contact trenches 332 with ions of the second conductivity type followed by rapid thermal annealing at around 730 C. Additionally at this time the epitaxial layer may be implanted with ions of the first conductivity type on a gradient to form the graded epitaxial layer 336.

Next as depicted in FIG. 3J a barrier layer 338 is formed in the emitter trenches 332 by deposition followed with rapid thermal annealing. The barrier layer may be made from any suitable barrier material and may be around 300 Angstrom to 500 Angstrom in thickness above the insulation layer for example titanium/titanium nitride. After formation of the barrier layer 338 the conductive emitter plug metal 334 and precursor to the emitter metal layer 335 may be formed by application of a molten metal or PVD or CVD deposition of the metal to the top surfaces of the semiconductor substrate composition. The metal may be any suitable metal, for example and without limitation,, aluminum,, tungsten or any alloy thereof. Next the precursor emitter metal layer 335 may be masked with a patterned mask via a suitable masking method and etched with suitable etchant to form the emitter metal layer 335 and gate metal layer (not shown) structures. After formation of the metal layers the device may be annealed by baking at around 400 C in a Hydrogen rich environment.

After annealing the device composition may be coated with silicon nitride layer and a Tetraethyl orthosilicate (TEOS) as a passivation layer. The passivation layer may then be masked by any suitable masking method followed by etching by an etch suitable for the passivation layer. Finally, a polyimide layer may be applied to the top of the device. The polyimide layer may be masked and etched to form the final polyimide layout. Additionally, not shown are the gate runners which may connect the gate electrodes the gate metal at the edge of the device.

After above wafer front side process finished, the wafer backside silicon was thinned down by wafer backside grinding process to the total thickness range of 60 micrometers to 80 micrometers. Then the wafer backside silicon may be doped with ions of the second conductivity type via ion implantation with a doping concentration of between 1e14 cm−3 and 1e16 cm−3 and an energy of implantation depending on the application but in some example implementations the energy may be between 20 Kiloelectronvolts (KeV) and 80 KeV. Then the wafer backside silicon may be deposited metal layers as collector via PVD or evaporation. The collector metal layer 337 may be any suitable conductive material such as, and without limitation, aluminum, copper, silver iron, magnesium, or an alloy thereof or a metal.

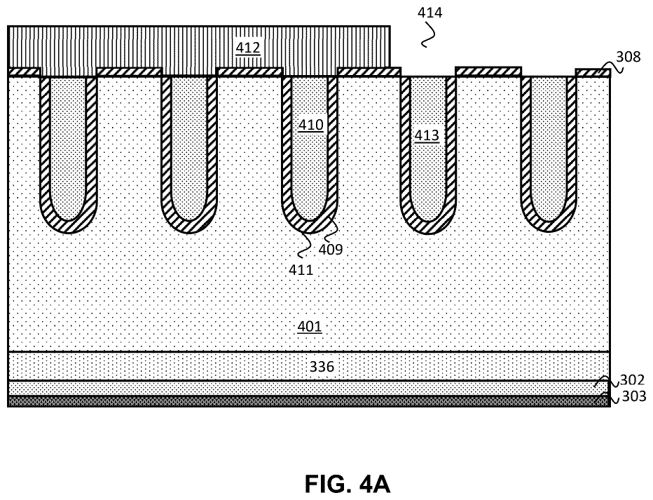

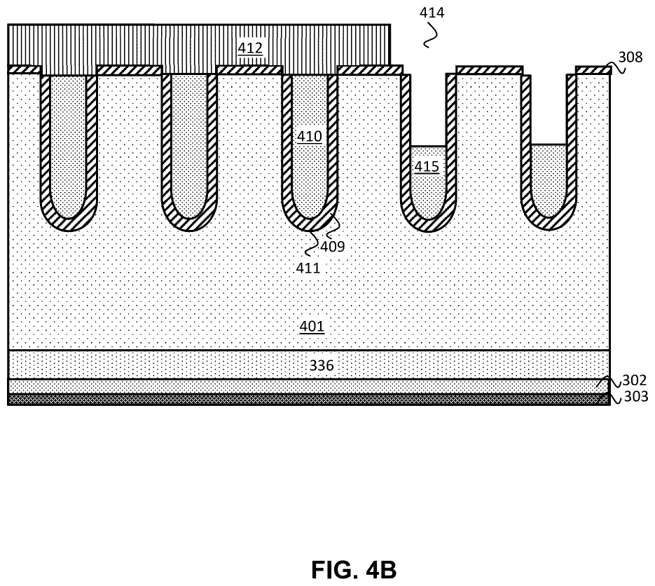

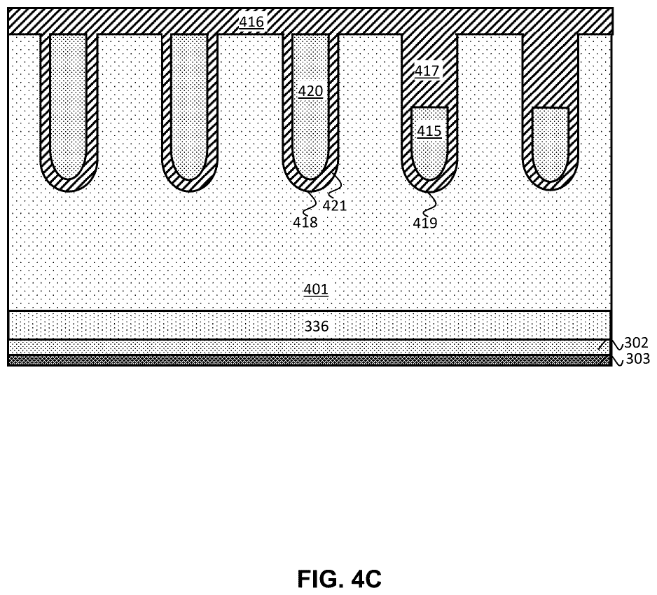

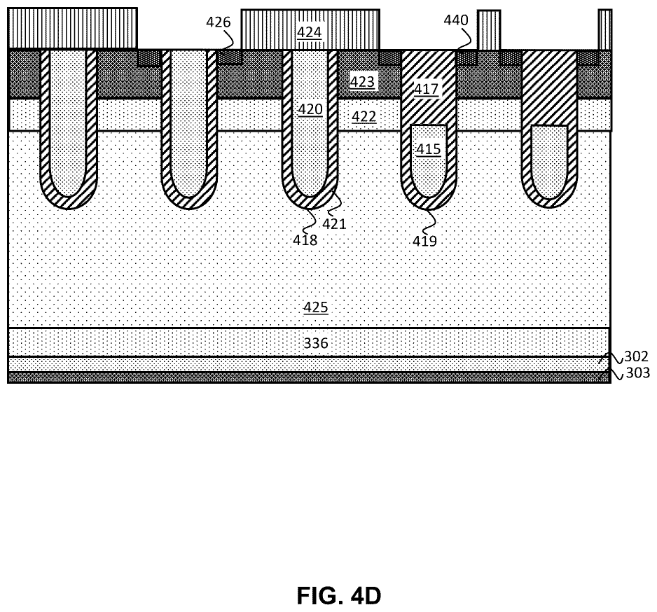

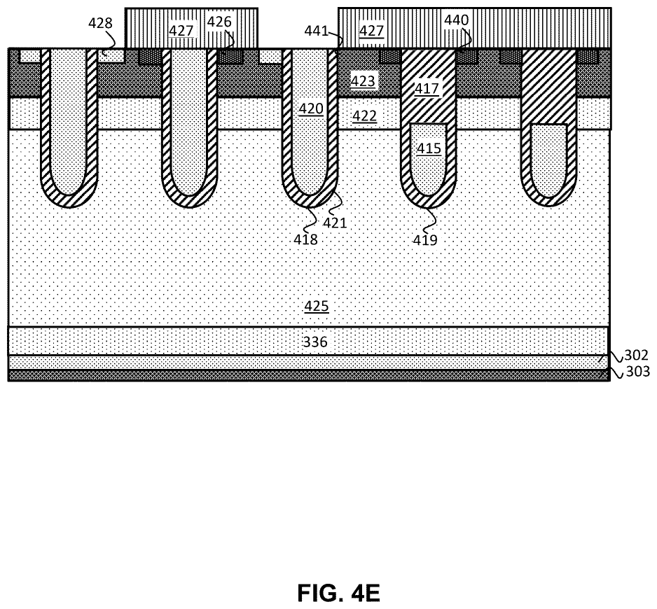

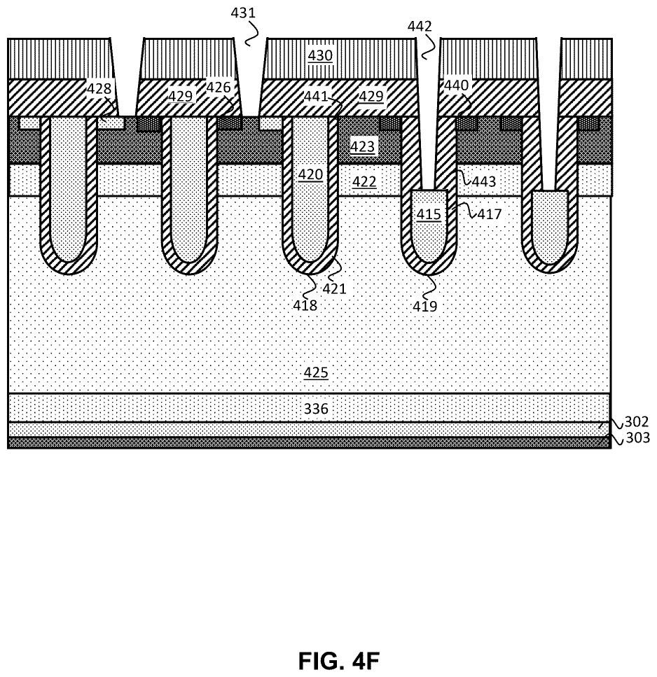

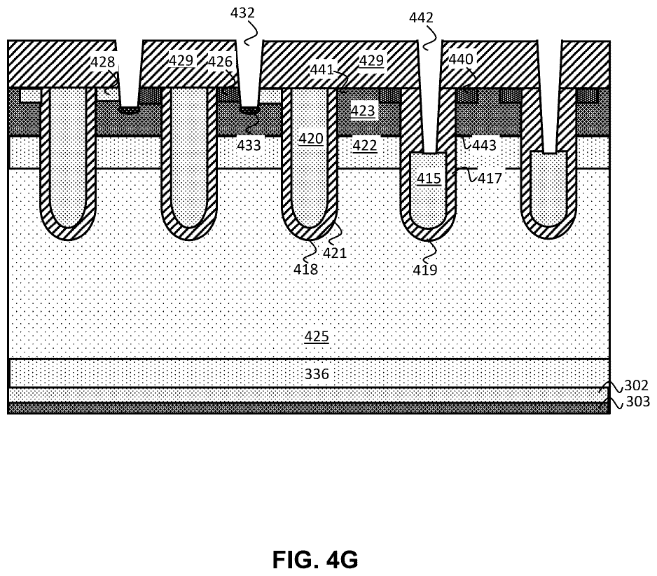

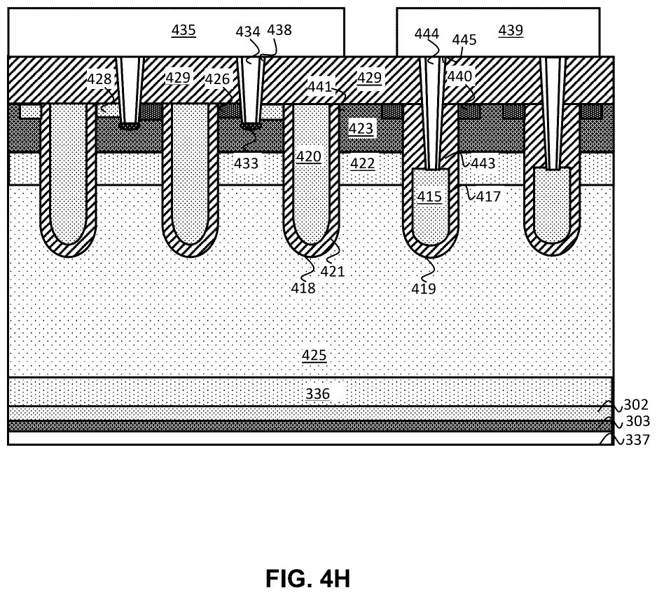

FIGS. 4A-4H depict a side view of a method for formation of the transistor device with dummy trenches having dummy electrodes and conductive dummy plugs as depicted in FIG. 2 according to aspects of the present disclosure. The method for formation as depicted here starts after formation of trenches 411 in the epitaxial layer 401 and filling those trenches with a trench insulation layer 409 and conductive electrode material as depicted in FIG. 3B.

As shown in FIG. 4A. a developed patterned mask 412 may be applied to the top surface of the semiconductor substrate composition. The developed patterned mask may be created, e.g., by first applying an undeveloped masking material to the top surface and patterning the mask with a suitable patterning method (e.g., a light pattern for a photoresist mask). The masking material may then be developed to form a patterned mask. By way of example and without limitation, a photoresist masking material may be exposed to a light pattern and subsequently developed and washed with the appropriate photoresist developer and wash leaving the patterned mask on the substrate. As shown the developed mask includes openings 414 in areas of the substrate that are precursors to dummy trench electrodes 413 and portions that cover the gate electrodes 410. Unlike in the previous implementation, in this implementation the active gate electrodes are located in a separate active area and dummy electrodes are located in a dedicated dummy area.

Next as depicted by FIG. 4B the conductive precursor dummy electrodes 413 are in etched to their final depth form dummy electrode 415. Here special care is taken to ensure that the dummy electrode 415 is etched to such that the top of the dummy electrode 415 is below a bottom of a body region which will be implanted into the substrate in later steps. The dummy electrode 415 may be etched by any suitable etching method for example and without limitation polycrystalline silicon dry etch.

The developed patterned mask 412 is then removed by any suitable mask removal method, for example and without limitation chemical washing. Next a dielectric material layer 416 may be deposited over the top surface of the substrate composition. The dielectric material fills the dummy trenches 419 over the dummy electrode 415 forming a top portion of the dummy electrode insulation layer 417. The Active gate trenches 418 are now differentiated from the dummy trenches 419 as the active gate trenches 418 are filled with a conductive gate electrode 420 formed over the active gate insulation layer 421 as shown in FIG. 4C. The dielectric material may be any suitable dielectric material for example and without limitation silicon dioxide. The dielectric material is then removed from the top surface of the substrate composition by for example and without limitation planarization and/or CMP leaving dummy trench portion 417 of the insulation layer.

As shown in FIG. 4D, the substrate composition may first be doped with ions of the first conductivity type to a depth deeper than the body region (yet to be formed) to form the carrier stored layer 422. The carrier stored layer 422 may be doped to a concentration slightly higher than that of the drift region 425. Here, the epitaxial layer has now become drift region 425. For example, and without limitation, the drift region may have an ion concentration of 1e13 cm⁻³ to 3e16 cm⁻³, if for example the drift region has a concentration of 2E13 to 2e16 cm⁻³ then the carrier stored layer may be doped to a concentration of 4e16 cm⁻³. Next the body region 423 may be formed above the carrier stored layer 422. The body region may be doped with ions of the second conductivity type via ion implantation with a doping concentration of between 1e12 cm⁻³ and 1e13 cm⁻³ and an energy of implantation depending on the application but in some example implementations the energy may be between 120 Kiloelectronvolts (KeV) and 200 KeV.

Next a patterned mask 424 for creation of the body contact regions 426 and dummy contact regions 440 may be formed on the top surface of the substrate composition. The patterned mask 424 may be formed any masking method such as the previously discussed masking method. The body contact regions 426 and dummy contact regions 440 are then formed through holes in the patterned mask 424 via a suitable doping method, for example and without limitation, ion implantation. The body contact regions may be more heavily doped with ions of the second conductivity type than the body region. After creation of the body contact regions the patterned body contact region mask 426 may be removed by a suitable removal method for example and without limitation chemical washing and/or CMP. The substrate composition may then undergo thermal annealing in a furnace at between 900 and 1000° C. in an O2-inert atmosphere or vacuum to drive the dopants into the substrate and activate them. The oxide layer on the surface of the substrate is then dipped back to 250 Angstroms. As shown the dummy contact regions 440 are located in a top portion of the body region near the sides of each of the dummy trenches 419.

Next as shown in 4E the emitter region patterned mask 427 is formed on the top surface of the of the substrate. The emitter region patterned mask 427 may be created via any mask patterning and development method such as those discussed above. Then the emitter regions 428 are implanted into the body region via for example and without limitation ion implantation. The emitter regions may be heavily doped with ions of the first conductivity type. After creation of the emitter regions the patterned emitter region patterned mask 427 may be removed by a suitable removal method for example and without limitation chemical washing. The substrate composition may then undergo thermal annealing in a furnace at between 200 and 1000° C. in an inert atmosphere or vacuum to drive the dopants into the substrate and activate them. Low temperature oxide is then deposited over the surface of the substrate to a thickness of 0.15 Micron. As can be seen in this implementation edge emitter regions may be omitted in areas 441 next to the dummy area to further reduce the chance of gate action by the dummy plugs.

Next as shown in FIG. 4F, the top portion of the insulation layer 429 is formed on the top surface of the substrate composition. The top portion of the insulation layer 429 may be formed by any suitable dielectric layer formation method for example and without limitation, deposition of Borophosophosilicate glass (BPSG) on the surface of the substrate via deposition and annealing/reflow. The top insulation layer thickness may vary depending on the application intended for the device. For example, and without limitation the top insulation layer may be 0.5 to 1 Microns in thickness A emitter contact plug patterned mask 430 is then formed over portions of the top insulation layer 429. The emitter contact plug patterned mask 430 may be formed by any suitable masking methods as discussed with other masks discussed above. Next the insulation layer is etched through holes in the emitter contact plug patterned mask 430 to form contact plug precursor trenches 431 and dummy plug trenches 442 in the insulation layer via any suitable dry oxide etching method. The dummy plug trenches 442 may be deeply etched through the dummy trench portion 417 of the insulating layer forming a dummy plug region 443 in the insulating layer that is thicker than areas of the insulating layer near a side of the dummy electrode 415. After creation of the contact plug precursor trenches 431, the emitter contact plug patterned mask 430 may be removed by a suitable removal method for example and without limitation chemical washing.

Then, as depicted in FIG. 4G, the semiconductor substrate may be etched to form the emitter contact trenches 432. The emitter contact trenches 432 may be etched by any suitable etching method to a depth in the semiconductor substrate composition of around 0.1 to 0.4 microns. Next a bottom contact region 433 may be implanted at the bottom of the emitter contact trenches 432 with ions of the second conductivity type followed by rapid thermal annealing at around 730° C.

Next, as depicted in FIG. 4H, an emitter plug barrier layer 438 is formed in the emitter trenches 332 and a dummy plug barrier layer 445 is formed in the dummy plug trenches 442 by deposition followed with rapid thermal annealing. The barrier layers may be made from any suitable barrier material and may be around 300 Angstrom to 500 Angstrom in thickness above the insulation layer for example titanium/titanium nitride. After formation of the barrier layers 438, 445 the conductive emitter plug metal 434, dummy plug metal 444, precursor to the emitter metal layer 435, precursor to the gate metal layer 439 may be formed by application of a molten metal or deposition of the metal to the top surfaces of the semiconductor substrate composition. The metal may be any suitable metal for example and without limitation, copper, aluminum, or any alloy thereof. Next the precursor emitter layer and gate layer may be masked with a patterned mask via a suitable masking method and etched with suitable etchant to form the emitter metal layer 335 and gate metal layer 439 structures. After formation of the metal layers the device may be annealed by baking at around 400° C. in a Hydrogen rich environment. As used here in, emitter plug and dummy plug may refer to both the emitter plug metal and emitter plug barrier layer, similarly the dummy plug may refer to dummy plug metal and dummy plug barrier layer.

After annealing the device composition may be coated with silicon nitride layer and a Tetraethyl orthosilicate (TEOS) as a passivation layer. The passivation layer may then be masked by any suitable masking method followed by etching by an etch suitable for the passivation layer. Finally, a polyimide layer may be applied to the top and bottom of the device. The polyimide layer may be masked and etched to form the final polyimide layout. Additionally, not shown are the gate runners which may connect the gate electrodes the gate metal at the edge of the device.

After the above-described wafer front side process finished, the wafer backside silicon was thinned down by wafer backside grinding process to the total thickness range of 60 um to 80 um. Then the wafer backside silicon may be doped with ions of the second conductivity type via ion implantation with a doping concentration of between 1e14 cm−3 and 1e16 cm−3 and an energy of implantation depending on the application but in some example implementations the energy may be between 20 Kiloelectronvolts (KeV) and 80 KeV. Then the wafer backside silicon may be deposited metal layers as collector via PVD or evaporation. The collector metal layer 337 may be any suitable conductive material such as, and without limitation, aluminum, copper, silver iron, magnesium, or an alloy thereof or a metal. Thus, an improved transistor cell design may be created using the improved dummy trench electrode design according to aspects of the present disclosure. The improved dummy trench electrodes may increase Cgc/Cge by decreasing Cge without increasing Cgc. Thus implementations may realize adjustment switching speed to reduce dv/dt to reduce EMI noise, and also a reduction in cell area, and turn on switching loss, with a large short-circuit safe operating area and a decrease in switching time without a corresponding increase in switching noise.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A,” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A semiconductor device comprising:
a substrate comprised of a semiconductor material having a drift region lightly doped with ions of a first conductivity type wherein the first conductivity type is opposite a second conductivity type;
a body region formed from the drift region, wherein the body region is doped with ions of the second conductivity type;
a dummy trench formed in the drift region, wherein the dummy trench is formed to a depth in the substrate deeper than a bottom depth of the body region;
a emitter region heavily doped with ions of the first conductivity type located in the body region;
an active gate trench formed in the drift region;
an insulation layer formed over the substrate, in the active gate trench and in the dummy trench;
a dummy electrode formed over the insulation layer in the dummy trench wherein the top of the dummy electrode is at a depth in the dummy trench below the bottom of the body region;
a gate electrode formed in the active gate trench wherein the gate electrode extends from a portion of the body region to below the bottom of the body region in the active gate trench.

2. The semiconductor device of claim 1 wherein the dummy electrode is conductively coupled a gate metal layer, and the gate electrode is conductive coupled to the gate metal layer.

3. The semiconductor device of claim 2 further comprising a dummy plug contact in the dummy electrode trench coupled between the dummy electrode and the gate metal.

4. The semiconductor device of claim 3 further comprising one or more dummy body contact regions located in the body region next to the dummy trench and heavily doped with ions of the second conductivity type.

5. The semiconductor device of claim 3 wherein the insulating layer includes a dummy plug region proximate to the dummy plug contact in the dummy electrode wherein the insulating layer in the dummy plug region is thicker than a region of the insulating layer near the dummy electrode.

6. The semiconductor device of claim 2 wherein the dummy trench is located underneath a gate metal layer and wherein the active gate trench is located underneath an emitter metal.

7. The semiconductor device of claim 1 further comprising one or more body contact regions heavily doped with ions of the second conductivity type and formed in an upper portion of the body region.

8. The semiconductor device of claim 6 wherein the one or more body contact regions include at least two body contact regions, wherein the at least two contact regions are located next the dummy trench in the substrate on opposing sides of the dummy trench.

9. The semiconductor device of claim 1 further comprising at least two emitter regions.

10. The semiconductor device of claim 9 wherein the at least two emitter regions are located next the active gate trench in the substrate on opposing sides of the active gate trench.

11. The semiconductor device of claim 1 further comprising a conductive emitter plug extending through the insulation layer and into the body region, wherein the emitter region is in contact with the conductive emitter plug.

12. The semiconductor device of claim 1 further comprising an emitter metal layer formed on at least portion of the insulation layer over a surface of the drift region.

13. The semiconductor device of claim 12 further comprising a metal collector layer formed on a side of the semiconductor substrate opposite the emitter metal layer.

14. The semiconductor device of claim 1 further comprising a collector region heavily doped with ions of the second conductivity located in a backside of the substrate on the side opposite the body the region.

15. The semiconductor device of claim 14 further comprising a buffer layer heavily doped with ions of the first conductivity type located proximate the backside of the substrate and at a depth in the substrate closer to the body region than the collector region.

16. The semiconductor device of claim 15 further comprising a graded epitaxial region having an ion concentration that changes with depth and located on the backside of the substrate above the buffer layer.

17. The semiconductor device of claim 1 further comprising a carrier storage layer formed in the drift region and doped with ions of the first conductivity type.

18. The semiconductor device of claim 1 further comprising at least two dummy trenches formed in the drift region wherein the dummy trench is formed to a depth in the substrate deeper than a bottom depth of the body region.

19. The semiconductor device of claim 18 wherein the active gate trench is located between two of the at least two dummy trenches in the drift region.

20. The semiconductor device of claim 1 further comprising at least two active gate trenches.

21. The semiconductor of claim 20 wherein the at least two active gate trenches are located in an active gate area of the drift region and the dummy trench is located in a dummy area of the drift region.
